(19) United States
(12) Patent Application Publication
(10) Pub. No.: US 2017/0097714 A1
(43) Pub. Date: Apr. 6, 2017

(54) TOUCH SCREEN PANEL, METHOD OF MANUFACTURING THE SAME, AND TOUCH DISPLAY DEVICE HAVING THE SAME

(71) Applicant: Samsung Display Co., Ltd., Yongin-si (KR)

(72) Inventors: Hyun-Ju LEE, Seoul (KR); Jin-Woo PARK, Cheonan-si (KR); Yoon-Gyu LEE, Seoul (KR)

(21) Appl. No.: 15/077,379

(22) Filed: Mar. 22, 2016

(30) Foreign Application Priority Data
Oct. 2, 2015 (KR) 10-2015-0138865

(51) Int. Cl. G06F 3/041; H01L 27/32; G02F 1/1333; G06F 3/044; G02F 1/1335

(52) U.S. Cl. CPC G06F 3/0414; G06F 3/0412; G06F 3/0416; G06F 3/044; G02F 1/133528; G02F 1/13338; H01L 27/323; G06F 2203/04103; G06F 2203/04101; G06F 2203/04105; G06F 2203/04111; G02F 2202/28

(57) ABSTRACT

A touch screen panel includes a polarizer, a touch electrode disposed on the polarizer, and a pressure sensitive layer disposed on the touch electrode, the pressure sensitive layer including a dielectric elastomer material and being configured to sense a change in capacitance based on a change of thickness of the pressure sensitive layer.

### CROSS-REFERENCE TO RELATED APPLICATION

This application claims priority from and the benefit of Korean Patent Application No. 10-2015-0138865, filed on Oct. 2, 2015, which is hereby incorporated by reference for all purposes as if fully set forth herein.

### BACKGROUND

Field

Exemplary embodiments relate to a touch screen panel, method of manufacturing the touch screen panel, and a touch display device having the touch screen panel. More particularly, exemplary embodiments relate to a touch screen panel capable of sensing electrical contact and pressure, method of manufacturing the touch screen panel, and a touch display is device having the touch screen panel.

Discussion of the Background

As demands on various types of display devices have increased with the development of an information society, studies on display devices, such as a liquid crystal display device (LCD), a plasma display panel (PDP), a field emission display device (FED), and electrophoretic display device (EPD), and an organic light emitting display device (OLED) have been actively conducted.

Recently, studies have been conducted to apply a touch screen panel function to such display devices. A touch screen panel is an input device, which enables a command to be input by touching a screen of a display device using an object, such as a finger or pen. Since a touch screen panel may substitute a separate input device connected to a display device, such as a keyboard or mouse, application fields thereof have been gradually extended.

Touch screen panels may be divided into a resistive overlay touch screen panel, a photosensitive touch screen panel, a capacitive touch screen panel, and the like. Among these touch screen panels, the capacitive touch screen panel may convert information of a contact position into an electrical signal, by sensing a change in capacitance formed between a conductive sensing pattern and an adjacent sensing pattern, ground electrode or the like, when an object, such as a user's hand or pen, comes in contact with the touch screen panel.

The change in capacitance is typically based on one of two principles. The first approach involves monitoring change of capacitance by the sensing system through direct electrical contact with a large capacitive object, usually a person through their finger. In certain cases, this type of sensor may also function to detect the proximity of an object to the touch sensor, thus, not requiring physical contact with the touch sensor. Because these systems often require a direct contact between a user and the sensing system, they may not work if, for example, the user is wearing a glove. Additionally, capacitive coupling may not be well suited for quantitatively measuring the applied pressure or proximity, but is capable of binary (on/off) sensing.

The second approach is associated with utilizing two conductive planes separated by a compressible and resilient dielectric. This composite forms a capacitor, in which the capacitance thereof depends in part on the distance between the conductive planes. When a pressure is applied, the compression to the dielectric changes the capacitance between the planes, which can be detected by the sensing system. By calibrating the compression with the applied force or pressure, this system can be used to quantify the force or pressure of the interaction with the sensor.

A touch screen panel may be directly formed on a back surface of a display panel. However, when defects occur in a touch sensor, the display panel directly formed with the touch screen panel may not be utilized.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a touch screen panel capable of sensing electrical contact and pressure, and reducing generation of defects. Exemplary embodiments further provide a method of manufacturing the touch screen panel And a touch display device having the touch screen panel.

Additional aspects will be set forth in the detailed description which follows, and, in part, will be apparent from the disclosure, or may be learned by practice of the inventive concept.

According to an exemplary embodiment of the present invention, a touch screen panel includes a polarizer, a touch electrode disposed on the polarizer, and a pressure sensitive layer disposed on the touch electrode, the pressure sensitive layer including a dielectric elastomer material and being configured to sense a change in capacitance based on a change of thickness of the pressure sensitive layer.

According to an exemplary embodiment of the present invention, a method of manufacturing a touch screen panel includes forming a touch electrode on a substrate, forming a protection film on the touch electrode, separating the touch electrode with the protection film from the substrate, attaching the separated touch electrode with the protection film to a polarizer, removing the protection film, and forming a pressure sensitive layer, the pressure sensitive layer including a dielectric elastomer material and being configured to sense a change in capacitance based on a change of thickness of the pressure sensitive layer.

According to an exemplary embodiment of the present invention, a touch display device includes a display panel configured to display an image and a touch screen panel including a polarizer, a touch electrode disposed on the polarizer, and a pressure sensitive layer disposed on the touch electrode, the pressure sensitive layer including a dielectric elastomer material and being configured to sense a change in capacitance based on a change of thickness of the pressure sensitive layer.

According to exemplary embodiments of the present invention, a touch screen panel includes a touch electrode and a pressure sensitive layer disposed on the touch electrode. The touch electrode is configured to sense a contact and the pressure sensitive layer is configured to sense a pressure, such that the touch screen panel senses the contact and the pressure.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view illustrating a touch screen panel according to an exemplary embodiment of the present invention.

FIG. 2 is a cross-sectional view taken along line I-I′ of FIG. 1.

FIG. 3 is a cross-sectional view illustrating a polarizer of a touch screen panel according to an exemplary embodiment of the present invention.

FIG. 4, FIG. 5, FIG. 6, FIG. 7, FIG. 8, and FIG. 9 are cross-sectional views illustrating a method of manufacturing the touch screen panel of FIG. 2.

FIG. 10 is a block diagram illustrating a method of manufacturing a touch display device according to an exemplary embodiment of the present invention.

FIG. 11 is a block diagram illustrating a method of manufacturing a touch screen panel according to an exemplary embodiment of the present invention.

FIG. 12 is a cross-sectional view illustrating a touch display device according to an exemplary embodiment of the present invention.

FIG. 13 is a cross-sectional view illustrating a display panel of the touch display device of FIG. 12, according to an exemplary embodiment of the present invention.

FIG. 14 is a cross-sectional view illustrating a display panel of the touch display device of FIG. 12, according to an exemplary embodiment of the present invention. and

FIG. 15 and FIG. 16 are cross-sectional views illustrating a sensing method of a touch electrode and a pressure sensitive layer according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at is other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

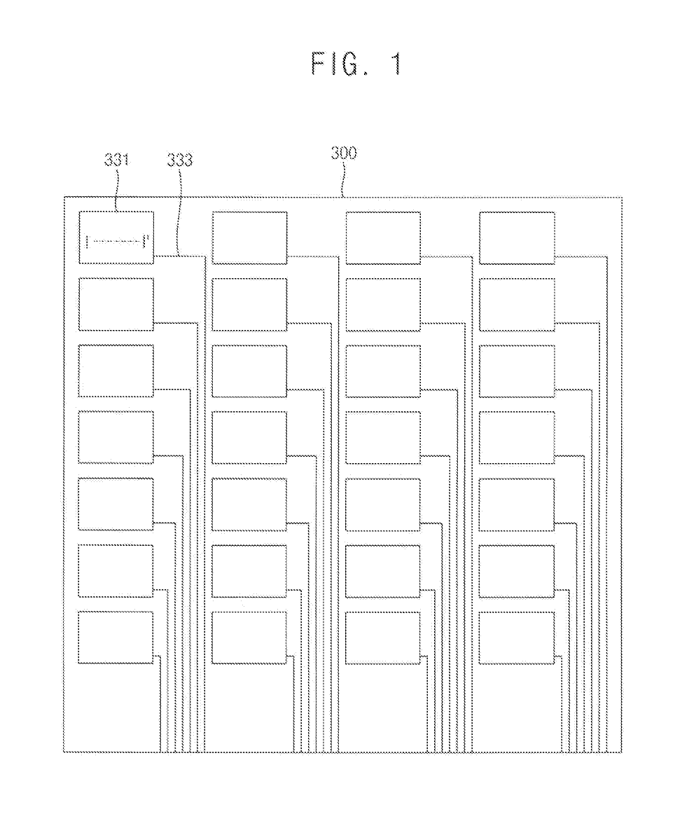

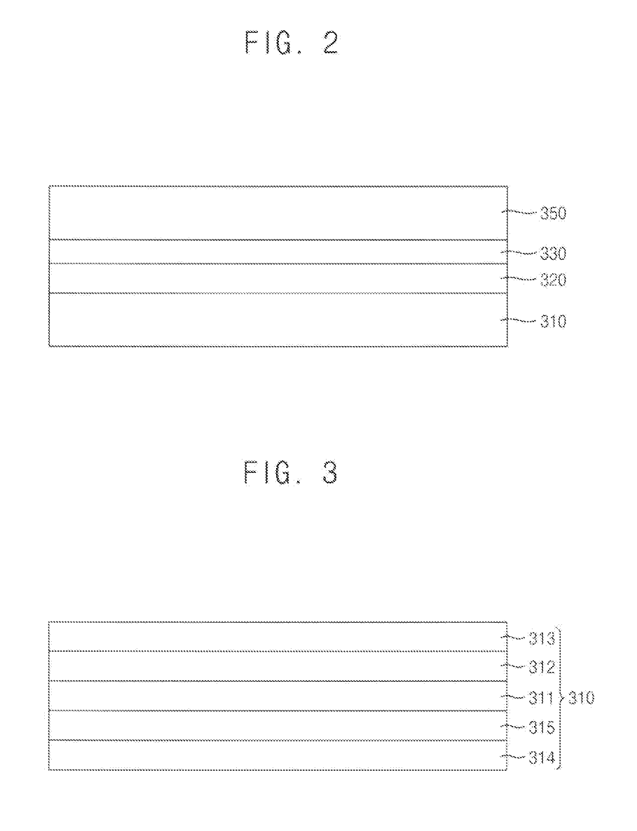

FIG. 1 is a plan view illustrating a touch screen panel according to an exemplary embodiment of the present invention. FIG. 2 is a cross-sectional view taken along line I-I′ of FIG. 1. FIG. 3 is a cross-sectional view illustrating a polarizer of a touch screen panel according to an exemplary embodiment of the present invention.

Referring to FIGS. 1 to 3, a touch screen panel 300 according to an exemplary embodiment of the present invention includes a polarizer 310, a second adhesive layer 320, a touch electrode 330, and a pressure sensitive layer 350.

The polarizer 310 includes a linear polarization member and a phase retardation film 314 disposed below the linear polarization member. The linear polarization member includes a polarizer layer 312, a lower supporter 311, and an upper supporter 313 supporting the polarizer layer 312. The polarizer layer 312 may include poly vinylalcohol (PVA). The lower supporter 311 and the upper supporter 313 may include triacetyl cellulous (TAC).

The phase retardation film 314 may be a X14 phase retardation film, and may convert a linear polarization into a circular polarization, or a circular polarization into a linear polarization. For example, the phase retardation film 314 may include a birefringence film, an alignment film of a liquid crystal polymer, or a film supporting an alignment layer of the liquid crystal polymer, or the like, which is formed by stretching a film made of a polymer, such as polycarbonate or polyvinyl alcohol, polystyrene or polymethyl methacrylate, polypropylene or other polyolefins, or polyacrylate or polyamide.

The polarizer 310 serves as a circular polarizer, because the linear polarization member, which linearly polarizes light in a set or predetermined direction, and a phase retardation film 314, which converts the linear polarization into the circular polarization, are attached.

A first adhesive layer 315 is formed between the linear polarization member and the phase retardation film 314, to attach the linear polarization member and the phase retardation film 314 to each other. The first adhesive layer 315, as pressure sensitivity adhesive layers (PSA), are formed in a film shape including an adhesive, and perform an adhering operation in response to pressure provided from the outside. Such an adhesive may include an acryl-based or rubber-based adhesive having a refractive index in a range of 1.46 to 1.52, and/or an adhesive containing particles, such as zirconia, to adjust the refractive index, and the like. The polarizer 310 may alternatively include various structures.

A second adhesive layer 320 is disposed on the polarizer 310 to attach the polarizer 310 and the touch electrode 330 to each other. The second adhesive layer 320 is initially disposed on the substrate SUB. The touch electrode 330 is then formed on the second adhesive layer 320. The second adhesive layer 320 with the touch electrode 330 is separated from the substrate SUB, and then the second adhesive layer 320 with the touch electrode 330 is attached to the polarizer 310.

The second adhesive layer 320 is formed in a film shape including an adhesive. Such an adhesive include an acryl-based or rubber-based adhesive having a refractive index in a range of 1.46 to 1.52, and/or an adhesive containing particles, such as zirconia, to adjust the refractive index, and the like. The second adhesive layer 320 may alternatively include various materials.

The touch electrode 330 is formed on the second adhesive layer 320. The touch electrode 330 includes a sensing pattern 331 and a connecting line 333. The sensing pattern 331 is made of a transparent conductive material having a predetermined transmittance or higher, so that light from a display panel may be transmitted therethrough, to implement the operation of the touch screen panel 300. Indium tin oxide (ITO) or indium zinc oxide (IZO) may be used as the transparent conductive material.

The connecting line 333 may include a low-resistance metallic material, such as molybdenum (Mo), silver (Ag), titanium (Ti), copper (Cu), aluminum (Al), or molybdenum/aluminum/molybdenum (Mo/Al/Mo). In addition, the connecting line 333 may include the same material as the sensing pattern 331. The connecting line 333 may be disposed on the same layer as the sensing pattern 331. Alternatively, the connecting line 333 may include different material as the sensing pattern 331 and/or disposed on a different layer as the sensing pattern 331.

The sensing pattern 331 is electrically connected to the connecting line 333. The touch screen panel according to an exemplary embodiment of the present invention is a capacitive touch screen panel. If the touch screen panel is contacted by an object, such as a user's finger or stylus pen, a change in capacitance from the contact is provided to an external driving circuit (not shown) through the connecting line 333. Then, the change in capacitance is converted into an electrical signal by an X and Y input processing circuit (not shown) or the like, so that the contact position is detected.

The pressure sensitive layer 350 is disposed on the touch electrode 330. The pressure sensitive layer 350 may be deformed by external pressure. Thus, the pressure may be sensed by a degree of change in the pressure sensitive layer 350, such as a thickness thereof.

The pressure sensitive layer 350 may include a material having restoring force and flexibility. In addition, the pressure sensitive layer 350 may include a dielectric material having predetermined permittivity for measuring a capacitance value. For example, the pressure sensitive layer 350 may include polyvinylidene fluoride (PVDF) or polyvinylidene fluoride-co-trifluoroethylene (PVFT). In addition, the pressure sensitive layer 350 may include adhesive material. The pressure sensitive layer 350 may attach the touch electrode 330 and the display panel DP. In addition, the pressure sensitive layer 350 may include transparent material. The pressure sensitive layer 350 may alternatively include different material having dielectric elastomer material.

The touch screen panel 300 according to the present exemplary embodiment includes the touch electrode 330 and the pressure sensitive layer 350 disposed on the touch electrode 330. Thus, the touch electrode 330 may sense contact, and the pressure sensitive layer 350 may sense pressure. Accordingly, the touch screen panel 300 may sense contact and pressure, so that detailed sensing may be performed.

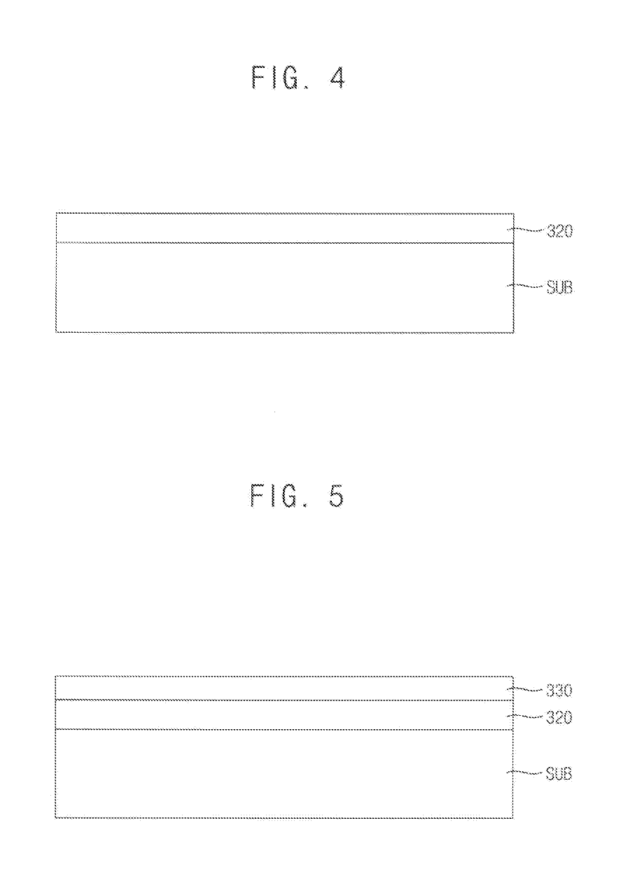

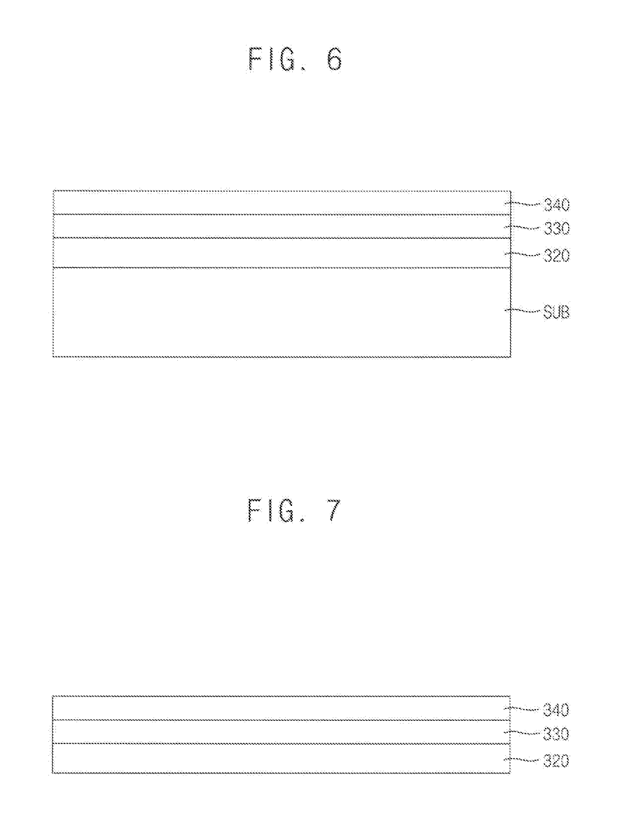

FIGS. 4 to 9 are cross-sectional views illustrating a method of manufacturing the touch screen panel of FIG. 2.

Referring to FIG. 4, the second adhesive layer 320 is formed on the substrate SUB. The substrate SUB may include a material which has relatively high transmittance, thermal resistance, and chemical resistance. For example, the substrate SUB may include any one of glass, polyethylenenaphthalate, polyethylene terephthalate, polyacryl, and a mixture thereof. After a touch electrode of a touch screen panel is formed, the substrate SUB may be separated from the touch electrode.

The second adhesive layer 320 is formed in a film shape including an adhesive. The adhesive may include an acryl-based or rubber-based adhesive having a refractive index in a range of 1.46 to 1.52, an adhesive containing particles, such as zirconia, in order to adjust the refractive index, or the like. The second adhesive layer 320 may alternatively include various materials.

Referring to FIG. 5, the touch electrode 330 is formed on the substrate SUB, on which the second adhesive layer 320 is formed.

The touch electrode 330 includes a sensing pattern 331 and a connecting line 333. The sensing pattern 331 is made of a transparent conductive material having a predetermined transmittance or higher, so that light from a display panel may be transmitted therethrough to implement the operation of the touch screen panel 300. Indium tin oxide (ITO) or indium zinc oxide (IZO) may be used as the transparent conductive material.

The connecting line 333 may include a low-resistance metallic material, such as molybdenum (Mo), silver (Ag), titanium (Ti), copper (Cu), aluminum (Al), or molybdenum/aluminum/molybdenum (Mo/Al/Mo). In addition, the connecting line 333 may include the same material as the sensing pattern 331. The connecting line 333 may be disposed on the same layer as the sensing pattern 331. Alternatively, the connecting line 333 may include different material as the sensing pattern 331 and/or disposed on a different layer as the sensing pattern 331.

The sensing pattern 331 is electrically connected to the connecting line 333. The touch screen panel according to an exemplary embodiment of the present invention is a capacitive touch screen panel. If the touch screen panel is contacted by an object, such as a user's finger or stylus pen, a change in capacitance from a contact is provided to a external driving circuit (not shown) through the connecting line 333. Then, the change in capacitance is converted into an electrical signal by an X and Y input processing circuit (not shown) or the like, so that the contact position is detected.

Referring to FIG. 6, a protection film 340 is disposed on the touch electrode 330. The protection film 340 may prevent the touch electrode 330 from being damaged from a scratch or the like. The protection film 340 may be a triacetyl cellulous film, which may be formed by saponifying a surface of an acetate-based resin, such as triacetyl cellulose with alkali or the like. After the touch electrode 330 is attached to the polarizer 310, the protection film 340 may be removed.

Referring to FIG. 7, the touch electrode 330, on which the protection film 340 is formed, is separated from the substrate SUB. The touch electrode 330 separated from the substrate SUB may be attached to the polarizer 310.

Referring to FIG. 8, the separated touch electrode 330 is attached to the polarizer 310. In this manner, the touch screen panel according to the present exemplary embodiment may include the polarizer 310, the second adhesive layer 320 disposed on the polarizer 310, the touch electrode 330 disposed on the second adhesive layer 320, and the protection film 340 disposed on the touch electrode 330. The configuration and constituent elements of the polarizer 310 according to the present exemplary embodiment may be substantially similar to the polarizer illustrated with reference to FIG. 3, and, thus, repeated description thereof will be omitted, in order to avoid obscuring exemplary embodiments described herein.

The protection film 340 is disposed on the touch electrode 330. The protection film 340 may prevent the touch electrode 330 from being damaged from a scratch or the like. The protection film 340 may be a triacetyl cellulous film, which may be formed by saponifying a surface of an acetate-based resin, such as triacetyl cellulose with alkali or the like.

Referring to FIG. 9, the protection film 340 disposed on the touch electrode 330 is removed. In this manner, the touch screen panel according to the present exemplary embodiment may include the polarizer 310, the second adhesive layer 320 disposed on the polarizer 310, and the touch electrode 330 disposed on the second adhesive layer 320.

Referring back to FIG. 2, the pressure sensitive layer 350 is disposed on the touch electrode 330 attached to the polarizer 310.

The pressure sensitive layer 350 is formed on the touch electrode 330 attached to the polarizer 310. The pressure sensitive layer 350 may be deformed by external pressure. Thus, the pressure may be sensed by a degree of change in the pressure sensitive layer 350, such as a thickness thereof.

The pressure sensitive layer 350 may include a material having restoring force and flexibility. In addition, the pressure sensitive layer 350 may include a dielectric material having predetermined permittivity for measuring a capacitance value. For example, the pressure sensitive layer 350 may include polyvinylidene fluoride (PVDF) or polyvinylidene fluoride-co-trifluoroethylene (PVFT). In addition, the pressure sensitive layer 350 may include adhesive material. The pressure sensitive layer 350 may attach the touch electrode 330 and the display panel DP. In addition, the pressure sensitive layer 350 may include transparent material. The pressure sensitive layer 350 may alternatively include different material having dielectric elastomer material.

The touch screen panel 300 according to the present exemplary embodiment includes the touch electrode 330 and the pressure sensitive layer 350 disposed on the touch electrode 330. Thus, the touch electrode 330 may sense contact, and the pressure sensitive layer 350 may sense pressure. Accordingly, the touch screen panel 300 senses contact and pressure, so that detailed sensing may be performed.

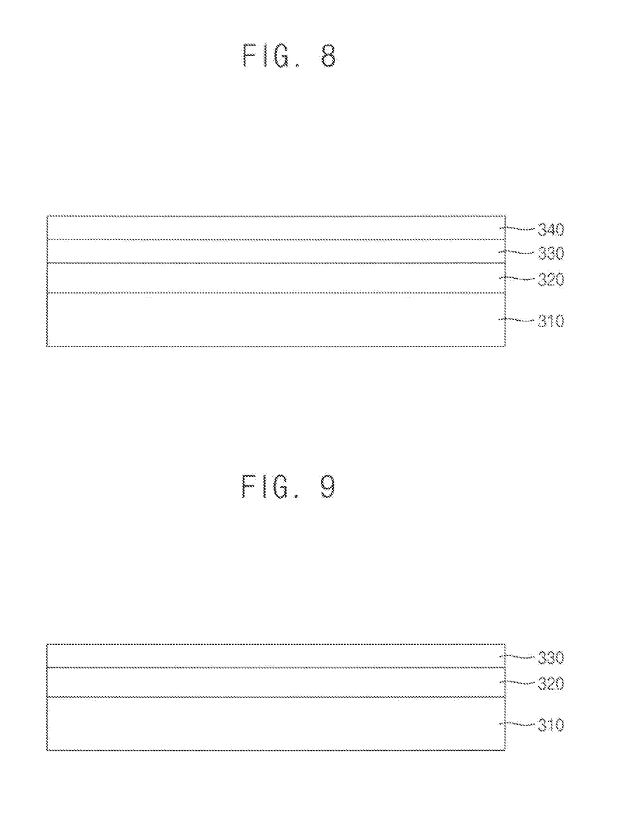

FIG. 10 is a block diagram illustrating a method of manufacturing a touch display device according to an exemplary embodiment of the present invention.

Referring to FIG. 10, a method of manufacturing a touch display device according to an exemplary embodiment of the present invention includes cell process (S100), forming touch panel with polarizer (S200), and attaching touch panel with polarizer (S300).

In the cell process, at step S100, a display panel is formed. A display panel according to the present exemplary embodiment may be an organic light emitting diode display panel or a liquid crystal display panel. Thus, the organic light emitting diode display panel or the liquid crystal display panel may be formed.

In the process of forming touch panel with polarizer, at step S200, a touch screen panel is integrally formed with a polarizer. The process of forming the touch panel with polarizer (S200) will be described in detail with reference to FIG. 11.

In the process of attaching touch panel with polarizer, at step S300, the touch screen panel integrally formed with the polarizer is attached to the display panel.

FIG. 11 is a block diagram illustrating a method of manufacturing a touch screen panel according to an exemplary embodiment of the present invention.

Referring to FIGS. 4 to 9 and FIG. 11, a method of manufacturing a touch screen panel according to an exemplary embodiment of the present invention includes forming touch electrode on substrate (S210), separating touch electrode from substrate (S220), attaching separated touch electrode to polarizer (S230), and forming pressure sensitive layer (S240).

In the process of forming touch electrode on substrate, at step S210, after the second adhesive layer 320 is disposed on the substrate SUB, the touch electrode 330 is disposed on the second adhesive layer 320. Thereafter, the protection film 340 is disposed on the touch electrode 330. It is noted that configurations and constituent elements of the second adhesive layer 320, the touch electrode 330, and the protection film 340 are substantially similar to those illustrated with reference to FIGS. 1 to 3, and, thus, repeated description thereof will be omitted, in order avoid obscuring the exemplary embodiments described herein.

In the process of separating touch electrode from substrate, at step S220, the touch electrode 330 on which the protection film 340 is formed is separated from the substrate SUB. The touch electrode 330 separated from the substrate SUB may be attached to the polarizer 310.

In the process of attaching separated touch electrode to polarizer, at step S230, the touch electrode 330 separated from the substrate SUB is attached to the polarizer 310. Thus, the touch screen panel according to the present exemplary embodiment may include the polarizer 310, the second adhesive layer 320 disposed on the polarizer 310, the touch electrode 330 disposed on the second adhesive layer 320, and the protection film 340 disposed on the touch electrode 330. The polarizer 310 according to the present exemplary embodiment may have substantially similar configuration and constituent elements with the polarizer illustrated with reference to FIG. 3, and, thus, repeated description thereof will be omitted.

In the process of forming pressure sensitive layer on touch electrode, at step S240, after the protection film 340 is removed, the pressure sensitive layer 350 is formed on the touch electrode 330 attached to the polarizer 310. The pressure sensitive layer 350 according to the present exemplary embodiment may have substantially similar configurations and constituent elements as the pressure sensitive layer illustrated with reference to FIG. 2, and thus, repeated description thereof will be omitted.

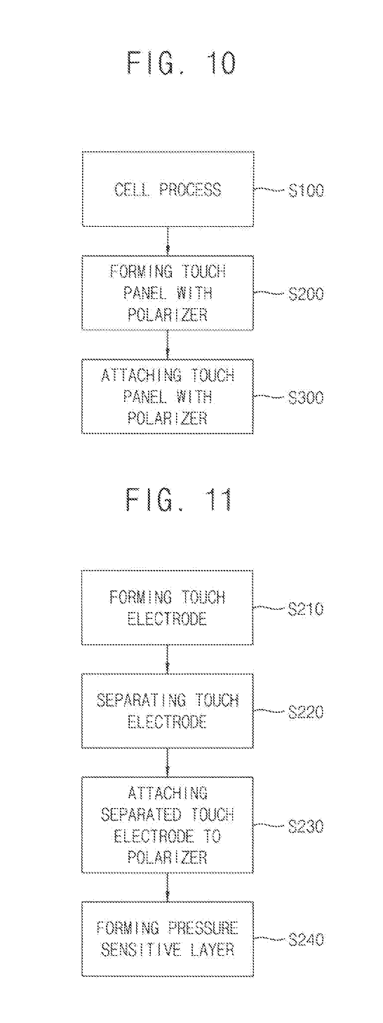

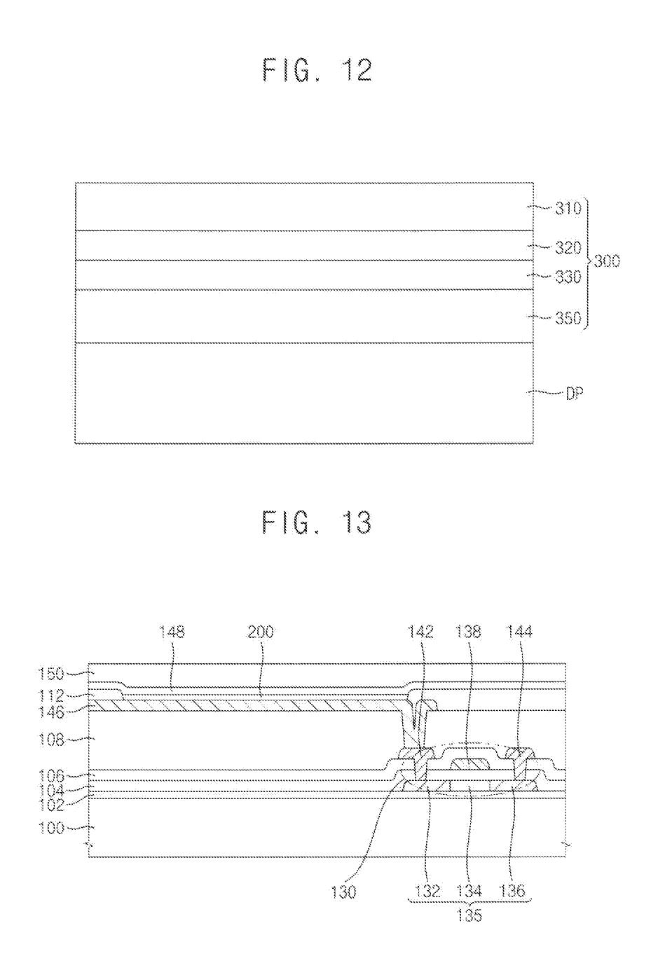

FIG. 12 is a cross-sectional view illustrating a touch display device according to an exemplary embodiment of the present invention.

Referring to FIG. 12, a touch display device according to the present exemplary embodiment includes a display panel DP configured to display an image and a touch screen panel 300 disposed on the display panel DP.

The touch screen panel 300 includes the polarizer 310, the second adhesive layer 320 disposed on the polarizer 310, the touch electrode 330 disposed on the second adhesive layer 320, and the pressure sensitive layer 350 disposed on the touch electrode 330. The pressure sensitive layer 350 includes dielectric elastomer material, and is configured to sense change of capacitance based on change of thickness.

A display panel according to the present exemplary embodiment may be an organic light emitting diode display panel or a liquid crystal display panel. Thus, a touch display device according to the present exemplary embodiment may be an organic light emitting diode touch display device or a liquid crystal touch display device.

FIG. 13 is a cross-sectional view illustrating a display panel of the touch display device of FIG. 12, according to an exemplary embodiment of the present invention.

Referring to FIGS. 12 to 13, the touch display device according to the present exemplary embodiment includes the display panel DP configured to display an image and the touch screen panel 300 disposed on the display panel DP. In the present exemplary embodiment, the touch display device is an organic light emitting diode touch display device.

The display panel DP includes a lower substrate 100, a buffer layer 102, a gate insulating layer 104, an insulating interlayer 106, a planarizing layer 108, a pixel defining layer is 112, a thin-film transistor (TFT) 130, a first electrode 146, a second electrode 148, an organic light emitting element 200, and a protecting layer 150.

The lower substrate 100 may include a transparent insulating substrate. For example, the lower substrate 100 may include a glass substrate, a quartz substrate, a transparent resin substrate including a transparent resin, etc. Examples of a transparent resin that may be used for the lower substrate 100 may include a polyimide resin, an acrylic resin, a polyacrylate resin, a polycarbonate resin, a polyether resin, a polyethylene terephthalate resin, and a sulfonic acid based resin, etc.

The buffer layer 102 is disposed on the lower substrate 100, and includes an insulating material. Examples of the insulating material that may be used for the buffer layer 102 may include an inorganic insulating material, such as silicon oxide (SiOₓ), silicon nitride (SiNₓ), silicon oxynitride (SiOₓN_{y}), silicon carbide (SiOₓC_{y}), silicon carbon-nitride (SiCₓN_{y}), etc. The inorganic insulating material may be used alone, a combination thereof, a mixture thereof, or a stacked structure thereof. When the buffer layer 102 includes the stacked structure, the buffer layer 102 may have a multi-layered structure including a silicon oxide layer, a silicon nitride layer, a silicon oxynitride layer, a silicon carbide layer and/or a silicon carbon-nitride layer.

The buffer layer 102 may prevent diffusion of metal atoms or impurities from the lower substrate 100, to control speed of heat transfer during subsequent crystallization process for an active pattern 135. Thus, electric characteristics of the active pattern 135 may be improved. Also, the buffer layer 102 planarizes a surface of the lower substrate 100.

The active pattern 135 is disposed on the buffer layer 102. For example, the active pattern 135 may include polysilicon. The active pattern 135 includes a drain contact portion 132, a source contact portion 136, and a channel portion 134. The drain contact portion 132 makes contact with a drain electrode 142 of a thin-film transistor 130. The source contact portion 136 makes contact with a source electrode 144 of the thin-film transistor 130. The channel portion 134 is interposed between the drain contact portion 132 and the source contact portion 136.

The gate insulating layer 104 is disposed on the buffer layer 102, on which the active pattern 135 is formed, to electrically insulate the active pattern 135 from the gate electrode 138 and a gate line (not shown). The gate insulating layer 104 may include silicon nitride, metal oxide, etc. Examples of an insulating material that may be used for the gate insulating layer 104 may include hafnium oxide (HfOₓ), aluminum oxide (AlOₓ), zirconium oxide (ZrOₓ), titanium oxide (TiOₓ), and tantalum oxide (TaOₓ), etc. These may be used alone, a combination thereof, a mixture thereof, or a stacked structure thereof. The gate insulating layer 104 may include contact holes, through which the source contact portion 136 and the drain contact portion 132 are exposed.

The gate electrode 138 is disposed on the gate insulating layer 104. The gate electrode 138 is disposed on the channel portion 134 of the active pattern 135. When a voltage difference is formed between the gate electrode 138 and the source electrode 144, the thin-film transistor 130 is turned on, so that a current flows through the channel portion 134 toward the drain electrode 142.

The gate electrode 138 may include a conductive material, such as metal, alloy, metal nitride, conductive metal oxide, and transparent conductive material, etc. Examples of the conductive material that may be used for the gate electrode 138 may include aluminum (Al), aluminum alloy, aluminum nitride (AlNₓ), silver (Ag), silver alloy, tungsten (W), tungsten nitride (WNₓ), copper (Cu), copper alloy, nickel (Ni), chromium (Cr), chromium nitride (CrNₓ), is molybdenum (Mo), molybdenum alloy, titanium (Ti), titanium nitride (TiNx), platinum (Pt), tantalum (Ta), tantalum nitride (TaNₓ), neodymium (Nd), scandium (Sc), strontium ruthenium oxide (SRO), zinc oxide (ZnOₓ), indium tin oxide (ITO), tin oxide (SnOₓ), indium oxide (InOₓ), gallium oxide (GaOₓ), indium zinc oxide (IZO), and etc. These can be used alone or in a combination thereof. Also, the gate electrode 138 may have a mono-layered structure or a multi-layered structure including a metal layer, an alloy layer, a metal nitride layer, a conductive metal oxide layer, and/or a transparent conductive material layer.

The insulating interlayer 106 is formed on the gate insulating layer 104, on which the gate electrode 138 and the gate line (not shown) are formed. The insulating interlayer 106 insulates the gate electrode 138 and the gate line (not shown) from the source electrode 144 and the drain electrode 142.

The insulating interlayer 106 may include silicon compound. Examples of an insulating material that may be used for the insulating interlayer 106 may include silicon oxide, silicon nitride, silicon oxynitride, silicon carbon-nitride, silicon carbide, etc. These may be used alone of in a combination thereof. The insulating interlayer 106 has contact holes, through which the source contact portion 136 and the drain contact portion 132 of the active pattern 135 are exposed.

The source electrode 144 and the drain electrode 142 are formed on the insulating interlayer 106. The source electrode 144 and the drain electrode 142 make contact with the source contact portion 136 and the drain contact portion 132 of the active pattern 135, respectively.

The source and drain electrodes 144 and 142 may include a conductive material, such as metal, alloy, metal nitride, conductive metal oxide, transparent conductive material, etc. Examples of the conductive material that may be used for the source and drain electrodes 144 and 142 may include aluminum (Al), aluminum alloy, aluminum nitride (AlNₓ), silver (Ag), silver alloy, tungsten (W), tungsten nitride (WNₓ), copper (Cu), copper alloy, nickel (Ni), chromium (Cr), chromium nitride (CrNₓ), molybdenum (Mo), molybdenum alloy, titanium (Ti), titanium nitride (TiNₓ), platinum (Pt), tantalum (Ta), tantalum nitride (TaNₓ), neodymium (Nd), scandium (Sc), strontium ruthenium oxide (SRO), zinc oxide (ZnOₓ), indium tin oxide (ITO), tin oxide (SnOₓ), indium oxide (InOₓ), gallium oxide (GaOₓ), and indium zinc oxide (IZO), etc. These can be used alone or in a combination thereof. Also, the source and drain electrodes 144 and 142 may have a mono-layered structure or a multi-layered structure including a metal layer, an alloy layer, a metal nitride layer, a conductive metal oxide layer, and/or a transparent conductive material layer.

The planarizing layer 108 is formed on the insulating interlayer 106, on which the source and drain electrodes 144 and 142 and the date line (not shown) are disposed, to electrically insulate the source electrode 144 from the first electrode 146. The planarizing layer 108 may include organic insulating material or inorganic insulating material. Examples of the insulating material that may be used for the planarizing layer 108 may include a photoresist, an acrylic resin, a polyimide resin, a polyamide resin, a siloxane resin, a photoresist acryl carboxyl resin, a novolak resin, an alkaline solable resin, silicon compound, silicon nitride, silicon oxynitride, silicon carbon-oxide, and silicon carbon-nitride, etc. These may be used alone or in a combination thereof.

The planarizing layer 108 has a contact hole through which the drain electrode 142 is exposed. The first electrode 146 is disposed on the planarizing layer 108 corresponding to the pixel region, and is electrically connected to the drain electrode 142 through the contact hole of the planarizing layer 108.

When the display panel DP has a front illumination type, the first electrode 146 may include a reflective metal, a reflective alloy, etc. For example, the first electrode 146 may include silver, platinum, gold, chromium, tungsten, molybdenum, titanium, palladium, iridium, and an alloy thereof, etc. These may be alone or in a combination thereof. Alternatively, the first electrode 146 may include a transparent conductive material, such as indium tin oxide, tin oxide, indium zinc oxide, zinc oxide, indium gallium oxide, and gallium oxide, etc. These may be used alone or in a combination thereof.

The pixel defining layer 112 is disposed on the planarizing layer 108, on which the first electrode 146 is formed, to expose a portion of the first electrode 146. The pixel defining layer 112 may include organic material or inorganic material. Examples of the material that may be used for the pixel defining layer 112 may include photoresist, a poly acrylic resin, a polyimide resin, an acrylic resin, and a silicon compound, etc. A display region and a non-display region are defined on the OLED by the exposed portion of the first electrode 146 that is exposed by the pixel defining layer 112. For example, the exposed portion of the first electrode 146, which is exposed by the pixel defining layer 112, corresponds to the display region. A remaining portion of the pixel defining layer 112 defines a non-display region.

The organic light emitting element 200 is disposed on the first electrode 146 that is exposed by the pixel defining layer 112. The second electrode 148 covers the organic light emitting element 200 and the pixel defining layer 112.

When the display panel DP has the front illumination type, the second electrode 148 may include a transparent conductive material. Examples of the transparent conductive material that may be used for the second electrode 148 may include indium tin oxide, tin oxide, is indium zinc oxide, zinc oxide, indium gallium oxide, and gallium oxide, etc. These may be used alone or in a combination thereof.

A touch screen panel according to the present exemplary embodiment has substantially similar configurations and constituent elements as the touch screen panel illustrated with reference to FIGS. 1 to 9, and, thus, same reference numerals are used for substantially similar elements, and repeated description thereof will be omitted.

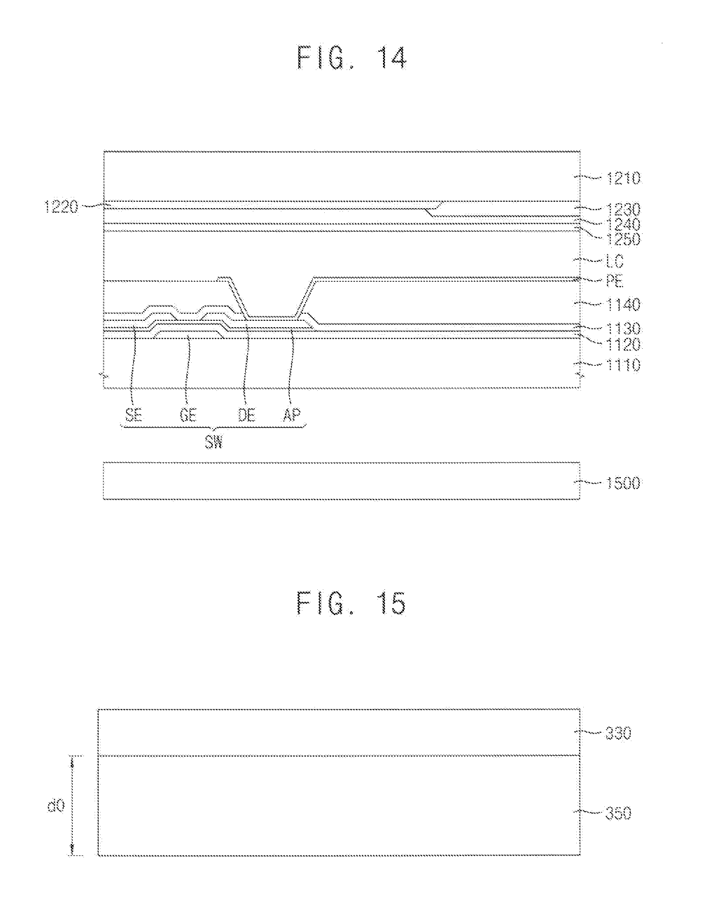

FIG. 14 is a cross-sectional view illustrating a display panel of the touch display device of FIG. 12, according to an exemplary embodiment of the present invention.

Referring to FIGS. 12 and 14, a touch display device according to an exemplary embodiment of the present invention includes a display panel DP configured to display an image and a touch screen panel 300 disposed on the display panel DP. In the present exemplary embodiment, the touch display device is a liquid crystal touch display device.

The display panel DP includes a lower substrate 1110, a gate electrode GE, a source electrode SE, a drain electrode DE, an active pattern AP, a pixel electrode PE, a first insulation layer 1120, a second insulation layer 1130, an organic layer 1140, a liquid crystal layer LC, an upper substrate 1210, a black matrix 1220, a color filter 1230, an over coating layer 1240, and a common electrode 1250. In addition, the display panel DP may further include a backlight assembly 1500 providing light to the display panel DP. Examples of the lower substrate 1110 may include a glass substrate, a quartz substrate, a silicon substrate, a plastic substrate and the like.

The gate electrode GE is disposed on the lower substrate 1110. The gate electrode GE is electrically connected with the gate line GL. The gate electrode GE may have a single layer structure including copper (Cu), silver (Ag), chrome (Cr), molybdenum (Mo), is aluminum (Al), titanium (Ti), manganese (Mn), and a mixture thereof. In addition, the gate electrode GE may have a multi layer structure having multiple layers including materials different from each other. For example, the gate electrode GE may include a copper layer and a titanium layer disposed on and/or under the copper layer.

The first insulation layer 1120 is formed on the gate electrode GE. The first insulation layer 1120 may cover the lower substrate 1110 and a first conductive pattern including the gate electrode GE. The first insulation layer 1120 may include an inorganic material, such as silicon oxide (SiOₓ) and/or silicon nitride (SiNₓ). For example, the first insulation layer 1120 includes silicon oxide (SiOₓ), and may have a thickness of about 500 Å. In addition, the first insulation layer 1120 may include multiple layers including different materials from each other.

An active pattern AP is formed on the first insulation layer 1120. The active pattern AP is formed on the first insulation layer 1120 in an area, in which the gate electrode GE is formed. The active pattern AP may be overlapped with the gate electrode GE. The active pattern AP may be partially overlapped with the source electrode SE and the drain electrode DE. The active pattern AP may be disposed between the gate electrode GE and the source electrode SE. The active pattern AP may be disposed between the gate electrode GE and the drain electrode DE.

The source electrode SE and the drain electrode DE may be formed on the active pattern AP. The source electrode SE and the drain electrode DE may be spaced apart from each other. The source electrode SE and the drain electrode DE may be formed from the same layer as a data line.

The source electrode SE and the drain electrode DE may have a single layer structure including copper (Cu), silver (Ag), chrome (Cr), molybdenum (Mo), aluminum (Al), is titanium (Ti), manganese (Mn), and a mixture thereof. In addition, the source electrode SE and the drain electrode DE may have a multi layer structure having multiple layers including materials different from each other. For example, the source electrode SE and the drain electrode DE may include a copper layer and a titanium layer disposed on and/or under the copper layer.

The second insulation layer 1130 may be formed on the source electrode SE and the drain electrode DE. The second insulation layer 1130 may be formed with a material including silicon oxide (SiOₓ) or silicon nitride (SiNₓ).

The organic layer 1140 is disposed on the second insulation layer 1130. The organic layer 1140 planarizes an upper surface of the substrate, so that defects due to the step formed, such as disconnection of a signal line, may be prevented. The organic layer 1140 may be an insulation layer including an organic material. The organic layer 1140 may be a color filter.

The pixel electrode PE is formed on the organic layer 1140. The pixel electrode PE may be electrically connected with the drain electrode DE through a first contact hole. The pixel electrode PE may include a transparent conductive material, such as indium tin oxide (ITO) and indium zinc oxide (IZO). In addition, the pixel electrode PE may include titanium (Ti) and/or molybdenum titanium (MoTi).

The upper substrate 1210 may include a glass substrate, a quartz substrate, a silicon substrate, a plastic substrate and the like.

The black matrix 1220 is disposed on the upper substrate 1210, to correspond to a gate line, a data line, a gate electrode GE, a source electrode SE, and a drain electrode DE. The black matrix 1220 blocks light and is disposed to correspond to a non-display area, on which an image is not displayed.

The color filter 1230 is disposed on upper substrate 1210, on which the black matrix 1220 is disposed. The color filter 1230 supplies colors to light passing through the liquid crystal layer LC. The color filter 1230 may include a red color filter, a green color filter, and blue color filter. The color filter 1230 corresponds to a unit pixel. The color filters adjacent to each other may have different colors. The color filter 1230 may be overlapped with adjacent color filter 1230 in a boundary of the adjacent unit pixels. In addition, the color filter 1230 may be spaced apart from adjacent color filter 1230 in the boundary of the adjacent unit pixels.

The over-coating layer 1240 is disposed on the color filter 1230 and the black matrix 1220. The over-coating layer 1240 flattens the color filter 1230, protects the color filter 1230, and insulates the color filter 1230. The over-coating layer 1240 may include acrylic-epoxy material.

The common electrode 1250 is disposed on the over-coating layer 1240. The liquid crystal layer LC is disposed between the lower substrate 1110 and the upper substrate 1210. The liquid crystal layer LC includes liquid crystal molecules having optical anisotropy. The liquid crystal molecules are driven by electric field, so that an image is displayed by passing or blocking light through the liquid crystal layer LC. In addition, the display panel DP may further include a backlight assembly 1500 providing light to the display panel DP.

A touch screen panel according to the present exemplary embodiment is substantially similar as the touch screen panel illustrated with reference to FIGS. 1 to 9, and thus, same reference numerals are used for the substantially similar elements and repeated descriptions thereof will be omitted.

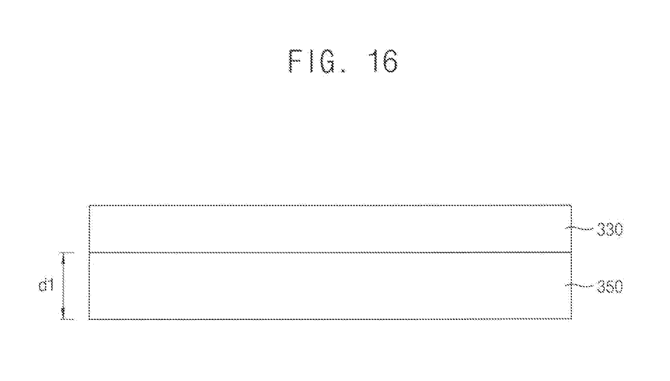

FIGS. 15 and 16 are cross-sectional views illustrating a sensing method of a touch electrode and a pressure sensitive layer according to an exemplary embodiment of the present invention.

Referring to FIGS. 15 to 16, a sensing method of a touch electrode and a pressure sensitive layer according to an exemplary embodiment of the present invention will be described. A touch screen panel according to an exemplary embodiment of the present invention a touch electrode 330 and a pressure sensitive layer 350.

The touch screen panel according to an exemplary embodiment of the present invention is a capacitive touch screen panel. If the touch screen panel is contacted by an object, such as a user's finger or stylus pen, a change of capacitance from the contact is provided to an external driving circuit (not shown) through the connecting line 333. Then, the change in capacitance is converted into an electrical signal by an X and Y input processing circuit (not shown) or the like, so that the contact position is detected.

The pressure sensitive layer 350 may include a material having restoring force and flexibility. In addition, the pressure sensitive layer 350 may include a dielectric material having predetermined permittivity for measuring a capacitance value. For example, the pressure sensitive layer 350 may include polyvinylidene fluoride (PVDF) or polyvinylidene fluoride-co-trifluoroethylene (PVFT). In addition, the pressure sensitive layer 350 may include adhesive material. The pressure sensitive layer 350 may attach the touch electrode 330 and the display panel DP. In addition, the pressure sensitive layer 350 may include transparent material. The pressure sensitive layer 350 may alternatively include different material having dielectric elastomer material.

The pressure sensitive layer 350 may sense change in capacitance based on change of thickness. The change in capacitance based on change of thickness of the pressure sensitive layer 350 is defined by the following Equation 1.

C=ε0×εr×A/d Eq. 1

In Equation 1, C may denote capacitance, A may denote an area of the pressure sensitive layer, ε0 may denote absolute permittivity of free space, εr may denote relative permittivity of the dielectric elastomer material, and d may denote the thickness of the pressure sensitive layer.

When pressure is not applied to the pressure sensitive layer 350, the pressure sensitive layer 350 has a first thickness d0. When pressure is applied to the pressure sensitive layer 350, the pressure sensitive layer 350 has a second thickness d1. When a thickness of the pressure sensitive layer 350 is changed from the first thickness d0 to the second thickness d1, capacitance may be changed. Accordingly, the pressure sensitive layer 350 may sense pressure based on change in thickness of the pressure sensitive layer 350.

According to exemplary embodiments of the present invention, a touch screen panel includes a touch electrode and a pressure sensitive layer disposed on the touch electrode. In this manner, the touch electrode may sense contact, and the pressure sensitive layer may sense pressure. Accordingly, the touch screen panel senses contact and pressure, so that detailed sensing may be performed.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. A touch screen panel, comprising:
a polarizer;
a touch electrode disposed on the polarizer; and
a pressure sensitive layer disposed on the touch electrode, the pressure sensitive layer comprising a dielectric elastomer material and being configured to sense a change in capacitance based on a change of thickness of the pressure sensitive layer.

2. The touch screen panel of claim 1, wherein the pressure sensitive layer comprises an adhesive material.

3. The touch screen panel of claim 1, wherein the pressure sensitive layer comprises a transparent material.

4. The touch screen panel of claim 1, wherein the pressure sensitive layer comprises at least one of polyvinylidene fluoride (PVDF) and polyvinylidene fluoride-co-trifluoroethylene (PVFT).

5. The touch screen panel of claim 4, wherein the change in capacitance based on change of thickness is defined by the following Equation:
C=ε0×εr×A/d,
wherein C is capacitance, A is an area of the pressure sensitive layer, ε0 is absolute permittivity of free space, εr is relative permittivity of the dielectric elastomer material, and d is thickness of the pressure sensitive layer.

6. The touch screen panel of claim 4, further comprising:
an adhesive layer disposed between the polarizer and the touch electrode.

7. A method of manufacturing a touch screen panel, the method comprising:
forming a touch electrode on a substrate;
forming a protection film on the touch electrode;
separating the touch electrode disposed with the protection film from the substrate;
attaching the separated touch electrode disposed with the protection film to a polarizer;
removing the protection film; and
forming a pressure sensitive layer on the touch electrode, the pressure sensitive layer comprising a dielectric elastomer material and being configured to sense a change in capacitance based on a change of thickness of the pressure sensitive layer.

8. The method of claim 7, wherein the pressure sensitive layer comprises an adhesive material.

9. The method of claim 7, wherein the pressure sensitive layer comprises a transparent material.

10. The method of claim 7, wherein the pressure sensitive layer comprises at least one of polyvinylidene fluoride (PVDF) and polyvinylidene fluoride-co-trifluoroethylene (PVFT).

11. The method of claim 7, wherein the change in capacitance based on change of thickness is defined by the following Equation:
C=ε0×εr×A/d,
wherein C is capacitance, A is an area of the pressure sensitive layer, ε0 is absolute permittivity of free space, εr is relative permittivity of the dielectric elastomer material, and d is thickness of the pressure sensitive layer.

12. The method of claim 7, wherein forming the touch electrode comprises:
forming an adhesive layer on the substrate; and
forming the touch electrode on the adhesive layer.

13. A touch display device, comprising:
a display panel configured to display an image; and
a touch screen panel comprising:
a polarizer;
a touch electrode disposed on the polarizer; and
a pressure sensitive layer disposed on the touch electrode, the pressure sensitive layer comprising a dielectric elastomer material and being configured to sense a change in capacitance based on a change of thickness of the pressure sensitive layer.

14. The touch display device of claim 13, wherein the pressure sensitive layer comprises an adhesive material.

15. The touch display device of claim 13, wherein the pressure sensitive layer comprises a transparent material.

16. The touch display device of claim 13, wherein the pressure sensitive layer comprises at least one of polyvinylidene fluoride (PVDF) and polyvinylidene fluoride-co-trifluoroethylene (PVFT).

17. The touch display device of claim 16, wherein the change in capacitance based on change of thickness is defined by the following Equation:
C=ε0×εr×A/d,
wherein C is capacitance, A is an area of the pressure sensitive layer, ε0 is absolute permittivity of free space, εr is relative permittivity of the dielectric elastomer material, and d is thickness of the pressure sensitive layer.

18. The touch display device of claim 13, further comprising:
an adhesive layer disposed between the polarizer and the touch electrode.

19. The touch display device of claim 13, wherein the display panel comprises:
a lower substrate comprising a thin-film transistor;
a first electrode electrically connected to the thin-film transistor;
an organic light emitting diode disposed on the thin-film transistor;
a second electrode covering the organic light emitting diode; and
a protecting layer disposed on the second electrode.

20. The touch display device of claim 13, further comprising:
a backlight assembly configured to provide light to the display panel, wherein the display panel comprises:
a lower substrate comprising a thin-film transistor;
an upper substrate facing the lower substrate; and
a liquid crystal layer disposed between the lower substrate and the upper substrate.
